(19) United States
(12) Patent Application Publication
(10) Pub. No.: US 2018/0226282 A1
(43) Pub. Date: Aug. 9, 2018

(54) NON-CONTACT SUBSTRATE TEMPERATURE MEASUREMENT TECHNIQUE BASED ON SPECTRAL INTEFEROMETRY

(71) Applicant: APPLIED MATERIALS, INC., Santa Clara, CA (US)

(72) Inventors: SIEW KIT HOI, Singapore (SG); Ananthkrishna JUPUDI, Singapore (SG); YUEH SHENG OW, Singapore (SG)

(21) Appl. No.: 15/887,446

(22) Filed: Feb. 2, 2018

Related U.S. Application Data
(60) Provisional application No. 62/454,642, filed on Feb. 3, 2017.

(51) Int. Cl. H01L 21/67; G01J 1/42; G01J 3/45; G01J 5/08; G01J 5/00

(52) U.S. Cl. CPC H01L 21/67248; H01L 21/67115; G01J 5/0007; G01J 3/45; G01J 5/0821; G01J 1/42

(57) ABSTRACT

In some embodiments, an apparatus for processing substrates includes: a substrate support within a processing chamber; a light source directly coupled to a light isolator and configured to deliver incident light to and through a first surface of the substrate when disposed on the substrate support; an optical fiber having a first end spaced apart a first distance from the first surface and a second end directly coupled to the light source via a coupling element; a photodetector directly coupled to the second end of the optical fiber via the coupling element and configured to receive a first reflected light beam reflected off the first surface and a second reflected light beam reflected off an inner boundary of a second surface of the substrate, opposite the first surface; and a signal processor to determine a temperature of the substrate based on the first and second reflected light beams.

### CROSS-REFERENCE TO RELATED APPLICATIONS

This application claims benefit of U.S. provisional patent application Ser. No. 62/454,642, filed Feb. 3, 2017, which is herein incorporated by reference in its entirety.

### FIELD

Embodiments of the present disclosure generally relate to substrate processing equipment.

### BACKGROUND

In conventional substrate processing chambers, the substrate processing temperature is controlled by providing heat exchangers around or in a substrate support for holding one or more substrates during processing. In a plasma environment, the temperature of the substrate might differ from the temperature of the heat exchanger provided in the process chamber. Accordingly, typical high vacuum and plasma processing chambers include apparatus for measuring and monitoring the substrate temperature. However, substrate temperature measurement in high vacuum and plasma processing chambers is not possible with contact methods, such as with thermocouples and the like. Consequently, current high vacuum and plasma processing chambers include apparatus and methods for performing a non-contact substrate temperature sensing and measurement. However, the inventors have discovered that the current non-contact substrate temperature measuring apparatus, such as infra-red pyrometers and the like have diminished accuracy when the transmittance and emissivity of the substrate changes due to changes in temperature. The inventors have also discovered that the current non-contact substrate temperature measurement methods are characterized by long signal sampling times which results in delayed temperature correction and poor film deposition.

Therefore, the inventors have provided improved apparatus and methods for non-contact measurement of substrate temperature during processing in a process chamber.

### SUMMARY

Methods and apparatus for measuring the temperature of substrates in substrate processing systems are provided herein. In some embodiments, an apparatus for processing substrates includes: a substrate processing chamber; a substrate support within the chamber to support a substrate for processing; a light source directly coupled to a light isolator and configured to deliver incident light to and through a first surface of the substrate when disposed on the substrate support; an optical fiber having a first end spaced apart a first distance from the first surface and a second end directly coupled to the light source via a coupling element; a photodetector directly coupled to the second end of the optical fiber via the coupling element and configured to receive a first reflected light beam reflected off the first surface and a second reflected light beam reflected off an inner boundary of a second surface of the substrate, opposite the first surface; and a signal processor to determine a temperature of the substrate based on the first and second reflected light beams.

In some embodiments, a method for method measuring a temperature of a substrate includes: (a) irradiating a substrate inside a processing chamber with light; (b) receiving a first reflection of the light from a first surface of the substrate; (c) receiving a second reflection of the light through the substrate from an inner boundary of a second surface opposite the first surface; and (d) determining a substrate temperature based on a spectral analysis of an interference pattern of the first and second reflections.

In some embodiments, a non-transitory computer readable medium having instructions stored thereon that, when executed, cause a method for measuring the temperature of a substrate to be performed. The method may include any of the embodiments disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic view of a substrate support including a temperature measuring apparatus in accordance with one or more embodiments of the present disclosure.

FIG. 2 a schematic view of an exemplary temperature measuring apparatus in accordance with one or more embodiments of the present enclosure.

FIG. 3 depicts a schematic view of an exemplary substrate holder in accordance with one or more embodiments of the present disclosure.

FIG. 4 depicts a method of measuring a temperature of a substrate in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide improved measurement and monitoring of the temperature of one or more substrates disposed in a process chamber. The disclosed methods and apparatus advantageously facilitate fast (e.g., real-time) and accurate measurements of the temperature of a substrate disposed or undergoing processing in a process chamber. Faster and more accurate measurements of the substrate temperature advantageously enable improved process uniformity by decreasing the time delay between a deviation from the set-temperature and the corrective action. Furthermore, the disclosed methods and apparatus facilitate improved substrate thickness control by providing a more robust temperature measurement technique.

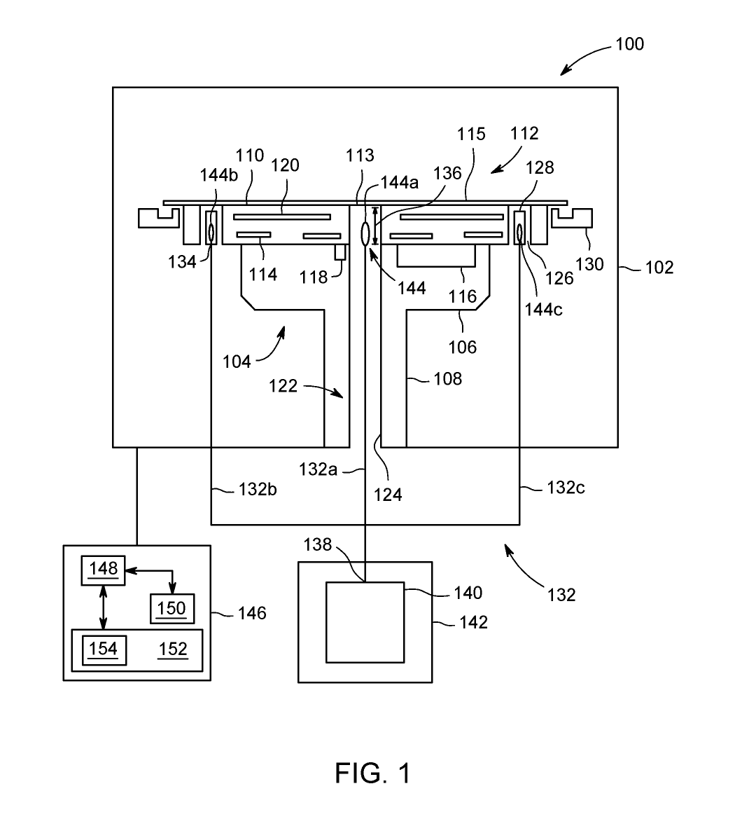

FIG. 1 is a schematic view of an exemplary substrate processing system 100 including a process chamber having a substrate support incorporating a temperature measuring apparatus in accordance with one or more embodiments of the present disclosure. Examples of suitable process chambers having a substrate support that may be suitably modified in accordance with the teachings provided herein include any of the ENDURA® line of physical vapor deposition (PVD) processing chambers, commercially available from Applied Materials, Inc., of Santa Clara, Calif. Substrate supports provided in other processing chambers from Applied Materials, Inc., or other manufacturers may also be adapted to benefit from the present disclosure.

The substrate processing system 100 includes a process chamber 102 enclosing an inner volume defined by the sidewalls, a bottom portion, and a top portion of the process chamber. A substrate support 104 is disposed in the inner volume of the process chamber 102. The substrate support 104 includes a base 106 and a support member 108. A top portion of the base 106 includes a substrate support surface 110 configured to receive and support a substrate 112. The substrate 112 has a first surface 113 and a second surface 115 opposite the first surface.

The temperature measurements in accordance to some embodiments of the present disclosure may be performed on one or more bare or coated substrates. In some embodiments, the temperature of a bare or coated substrate having a thickness of about 10 μm to about 900 μm, for example about 760 μm, may be measured. Suitable substrates include but are not limited to bare silicon, metal coated silicon, and silicon substrates coated with other suitable materials.

In some embodiments, the substrate support 104 may optionally include a heating apparatus 114 disposed in the base 106, for providing heat to the base 106. In some embodiments, the heating apparatus 114 is a resistive heater disposed in the base 106. Alternatively or in combination, in some embodiments, the heating apparatus is one or more of an infra-red, an ultra-violet, or a microwave heat source.

In some embodiments, the base 106 may further include a cooling apparatus 116. In some embodiments, the cooling apparatus 116 includes one or more passageways for flowing a heat transfer medium, for example, coolant for cooling the base 106.

The substrate support 104 may also include a temperature monitor 118 for monitoring the temperature of the base 106, and a thermal profile across the base 106 and the substrate support surface 110. In some embodiments, the temperature monitor 118 may be a thermocouple disposed in the base 106.

In some embodiments, the substrate support 104 may be a vacuum or an electrostatic chuck (ESC). In some embodiments, the substrate support 104 may further include processing apparatus such as electrodes for RF bias, pulsed DC bias, and the like. In the exemplary embodiment depicted in FIG. 1, one or more electrodes 120 are disposed in the base 106.

An opening 122 having an inner wall 124 is formed in the support member 108, through a central axis of the substrate support 104 and perpendicular to the substrate support surface 110. The opening 122 may be disposed in any suitable location that will be covered by the substrate 112 when disposed on the substrate support surface 110. In some embodiments, the opening 122 is disposed in the center of the substrate support surface 110 (or in a location corresponding to the center of the substrate 112 when disposed on the substrate support surface 110). In some embodiments, the opening 122 is a gas hole provided to direct one or more gases to the backside of substrate 112 when disposed on the substrate support surface 110.

The substrate support 104 further includes a plurality of holes 126 formed through the base 106 and spaced apart from the opening 122. In some embodiments, the holes 126 are disposed about the opening 122 and proximate to the periphery of the base 106. In some embodiments, for example in a substrate support designed for handling 300 mm wafers or similar substrates, each of the holes 126 may be located about 127 mm from the opening 122. Other radial locations may also be used, in particular in substrate supports designed for operation with substrates having other dimensions.

A plurality of lift pins 128 are movably disposed through the holes 126. The lift pins 128 are configured to be light-permeable in the vertical direction. In some embodiments, the lift pins 128 may be hollow. The lift pins 128 are vertically movable with respect to the base 106. The lift pins 128 are configured to extend through the holes 126 to transfer a substrate 112 onto or away from the substrate support surface 110.

In some embodiments, the process chamber 102 may include a dielectric ring 130 (e.g., a deposition ring) which may be used to shield the periphery of the substrate 112 from deposition. For example, the dielectric ring 130 may be disposed about a peripheral edge of the substrate support 104 and adjacent to the substrate support surface 110 as illustrated in FIG. 1.

An optical fiber 132 (three optical fibers shown in FIG. 1, 132a, 132b, 132c) having a first end 134 spaced apart a first distance 136 from the substrate support surface 110 and a second end 138 coupled to a coupling element 140 provided as part of measurement equipment 142 disposed outside the process chamber 102. The first distance 136 is defined to prevent any contact between the first end 134 and the first surface 113 of the substrate 112 when disposed on the substrate support surface 110.

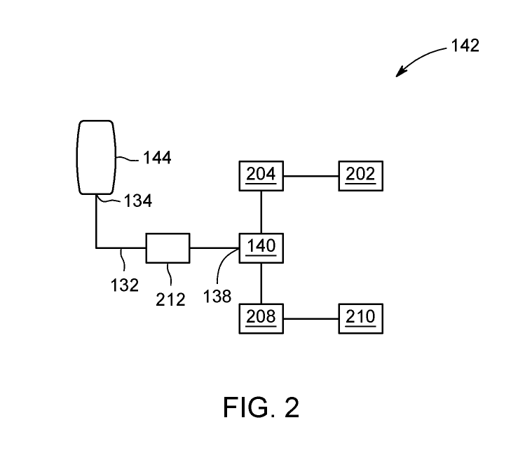

The coupling element 140 (e.g., a coupler) is provided to provide coupling between one or more optical fibers provided to send and receive light into the process chamber (e.g., optical fibers 132a, 132b, 132c) and optical fibers provided to either carry light from a light providing unit of (e.g., light source 202, shown in FIG. 2) or to photo-detecting unit (e.g., photodetector 208, shown in FIG. 2). Light from the light source 202 interferes with the reflected light from wafer at the coupler. The interference signal is then measured by the photodetector 208. For example, 1300 nm 1×2 or 2×2 couplers with a 50:50 coupling ratio are suitable for coupling the optical fibers.

In the exemplary embodiment depicted in FIG. 1, a plurality of optical fibers (e.g., 132a, 132b, and 132c) are provided to carry separate light beams from the coupling element 140 to different locations of the substrate support surface 110 (e.g., different areas on the first surface 113 of a substrate 112, when disposed thereon). For example, a first optical fiber 132a is disposed through a center of the substrate support 104 and second and third optical fibers 132b, 132c are provided through separate lift pin holes 126. In some embodiments, a fourth optical fiber (not shown), may be provided through a different lift pin hole (for example, when three lift pins and corresponding holes are provided in the substrate support).

The first ends 134 of the optical fibers 132 are respectively disposed in the opening 122 or one of the holes 126. In embodiments where the optical fibers 132 are disposed in the holes 126, the first end 134 may optionally further be disposed within a lift pin 128. The first end 134 of each optical fiber 132 is coupled to an optical probe 144, as illustrated in FIG. 1 by the optical probe 144a disposed in the opening 122 and the optical probes 144b, 144c disposed in the lift pins 128. The optical probe 144 includes a body having a tail configured to receive the first end 134. The optical probe further includes a head extending from the body and having a window disposed on an edge of the head opposite the tail. The window is transparent to light provided from or into the optical probe 144.

In embodiments where the optical probe 144 is disposed in the opening 122, one or more probe holders may be disposed between the inner wall 124 of the opening 122 and the optical probe 144. When provided, the probe holders vertically align and retain the optical probe 144 within the opening 122. In some embodiments, the probe holders are further configured to allow passage of gases around the optical probe 144.

FIG. 2 shows a schematic view of an exemplary temperature measuring apparatus depicting further components of the measurement equipment 142. The optical fiber 132 operatively couples the optical probe 144 to a light source 202. The light source 202 is directly coupled to an isolating element 204 disposed between the light source 202 and the coupling element 140. Light provided by the light source 202 propagates inside the optical fiber 132, from the second end 138 to the first end 134 to be incident on the first surface 113.

In some embodiments, the light source 202 is configured to provide light having a suitable wavelength, such as between about 1100 nm and about 1700 nm. In some embodiments, the wavelength is selected according to the first distance 136. For example, in some embodiments the light source 202 may provide light having a wavelength about 1300 nm where the first distance 136 is about 155 mm. In some embodiments, the light source 202 may provide an incident light spot size of about 60 μm².

In some embodiments, the light source 202 may be an amplified spontaneous emission (ASE) light source. For example, in some embodiments, the light source 202 may be a superluminiscent diode (SLD). In some embodiments, the light source 202 may be suitable for low-coherence interferometry.

The isolating element 204 is provided to allow the transmission of light in only the direction, e.g., from the light source 202 to the coupling element 140. The isolating element 204 prevents unwanted light from entering the light source or interfering with the light provided by the light source. For example, the isolating element 204 can be an infrared (IR) fiber optic isolator with an operating wavelength range of about 1295 to about 1325 nm. The isolating element typically can provide isolation of greater than or equal to about 29 dB.

The optical fiber 132 further operatively couples the optical probe 144 to a photodetector 208. The photodetector 208 (e.g., a light detector) detects light reflected from the substrate 112, for example a first reflected beam from the first surface 113, and a second reflected beam from an inner boundary of the second surface 115. Reflected light beams travel the length of the optical fiber 132, from the first end 134 to the second end 138 to be detected and received by the photodetector 208.

The photodetector 208 is coupled to a signal processor 210. In some embodiments the photodetector 208 is directly coupled to the signal processor 210. In some embodiments, the signal processor 210 includes a spectrum analyzer configured to perform spectral interferometry of the reflected light beams, for example, by curve-fitting, Fast Fourier Transform (FFT), or similar methods.

In some embodiments, the measurement equipment 142 further includes a multiplexing unit 212 disposed between the coupling element 140 and the second end 138 of each optical fiber 132 (e.g., optical fibers 132a, 132b, 132c). Although one optical fiber 132 and optical probe 144 is shown in FIG. 2 for clarity, the multiplexing unit 212 is generally coupled to multiple optical fibers, such as optical fibers 132a, 132b, 132c and respective optical proves 144a, 144b, 144c, (as shown in FIG. 1). The multiplexing unit 212 includes a multiplexer and a de-multiplexer. The multiplexing unit 212 advantageously facilitates simultaneous measurement at multiple points in order to monitor/control temperature uniformity during processing. The multiplexing unit 212 combines several input signals (e.g., from probes) into one signal path to carry the light to the photodetector. Alternatively, multiple detectors can be provided to achieve the same purpose without the multiplexing unit.

The de-multiplexer is operatively coupled to the light source 202 and provided to split a light beam from the light source 202 into separate light beams for delivery to one or more different locations of the substrate support surface 110 (e.g., areas on the first surface 113 disposed above the first end 134 of optical fibers 132a, 132b, and 132c, when provided).

The multiplexer is operatively coupled to the photodetector 208. The multiplexer is a signal selector that selectively passes reflected light beams from the one or more different locations to the photodetector 208. For example, in some embodiments, the multiplexer may include a rotary switch.

In some embodiments, the multiplexing unit 212 may be a wavelength-division multiplexing (WDM) system. In some embodiments, the multiplexing unit 212 may be a polarization-division multiplexing (PDM) system.

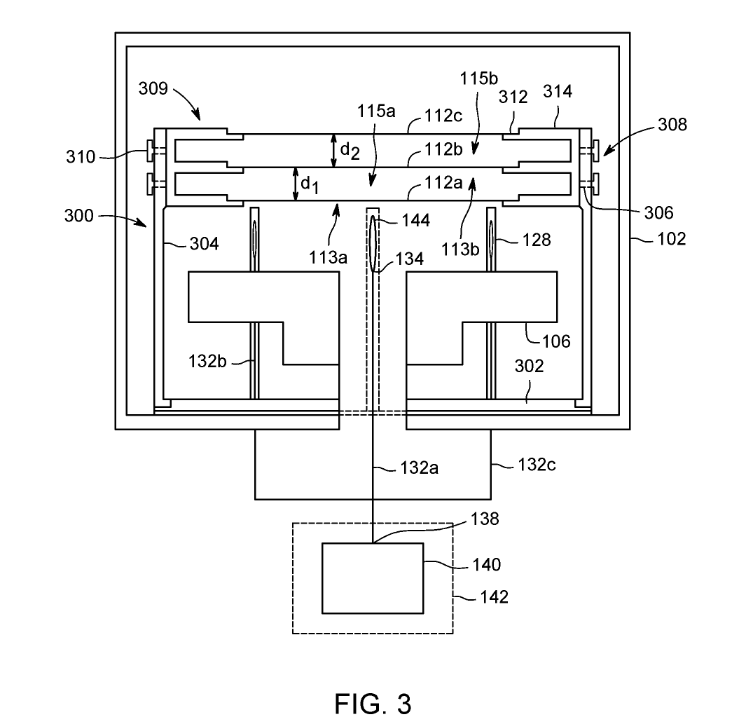

FIG. 3 depicts a schematic view of an exemplary substrate holder in accordance at least with some embodiments of the present disclosure. As depicted in FIG. 3, the process chamber 102 may alternatively include a multiple-substrate holder 300 disposed about the substrate support 104. Although shown in one exemplary configuration, teachings of the present disclosure may be adapted to multiple-substrate holders having other configurations as well.

In some embodiments, the multiple-substrate holder 300 includes a bottom member 302 having one or more vertical supports 304 extending from the bottom member 302. A plurality of vertically spaced apart substrate support planes are attached to the vertical supports. Each substrate support plane is configured to hold a substrate such that multiple substrates can be disposed in the process chamber. For example, in some embodiments, the vertical supports 304 may further include one or more mounting holes 306 for receiving a peripheral member 308. The peripheral members 308 may be configured to support a substrate, for example, proximate the peripheral edge of the substrate. In some embodiments, the bottom member 302 and the vertical supports may be fabricated from aluminum or other suitable process-compatible material.

One or more fasteners 310 are provided, for example, along with the peripheral member 308 to fasten the peripheral member 308 to the vertical supports 304 through the mounting holes 306.

The multiple-substrate holder 300 is configured to hold a plurality of substrates. In some embodiments, the plurality of substrates may be arranged in a stack configured to grow from a first substrate at one end closest to the first end 134 of the optical fiber 132 to an N^{th} substrate at an opposite end furthest from the first end 134.

In some embodiments having vertically arranged substrates, the top substrate may be designated a first substrate, for example, if the first end 134 is disposed above the stack. In other embodiments having vertically arranged multiple substrates, the bottom substrate may be designated the first substrate, for example, if the first end 134 is disposed beneath the stack. Accordingly, in the exemplary embodiment depicted in FIG. 3, showing a total of three substrates, 112a is the first substrate, 112b is the second substrate, and 112c is the N^{th} substrate.

In some embodiments, the peripheral member 308 may include a plurality of vertically arranged substrate support members 309. The plurality of substrate support members 309 include a blade region 312 disposed beneath and radially inward of a plate region 314. In some embodiments, the blade region 312 may be made of ceramic or other suitable process-compatible material. In some embodiments, the plate region 314 may be made from a nickel-based alloys (such as an alloy comprising nickel, iron, and cobalt), for example KOVAR®.

In the exemplary embodiment depicted in FIG. 3, the peripheral member 308 includes two oppositely facing semi-circular components disposed about the substrate support 104. The plurality of substrate support members 309 of the peripheral member 308 define an annular region having a radius configured to be smaller than the radii of the substrates 112 (e.g., substrates 112a, 112b, 112c, etc.). In some embodiments, the substrate support members 309 may be continuous hoops having fixed radii.

The plurality of substrate support members 309 are spaced apart to define a series of gaps d₁ to d_{N}, between adjacent surfaces of plural substrates, when present. For example, a gap d₁ is defined between the second surface 115a of the first substrate 112a and the first surface 113b of the second substrate 112b. Similarly, respective gaps are formed between successive adjacent substrates and a gap d_{N} is defined between the N^{th-1} and N^{th} substrate. In some embodiments, the gaps d₁ to d_{N} may have different lengths. In other embodiments, the gaps d₁ to d_{N} may be equal in length. For example, in some embodiments, the gaps d₁ to d_{N} may each be about 400 μm.

The index of refraction of the material disposed in the gaps d₁ to d_{N} is different from the index of refraction of the substrate material. In accordance with some embodiments of the present disclosure, the index of refraction of the material disposed in the gaps d₁ to d_{N} may be lower than the index of refraction of the substrate material. For example, the gaps d₁ to d_{N} may comprise air or process gases within the process chamber 102.

In operation, as illustrated in FIG. 1, the substrate 112 is loaded into the process chamber 102 and disposed on top of the substrate support surface 110. The substrate 112 is disposed such that the first surface 113 covers the opening 122 and faces the first end 134 of the optical fiber 132 placed the first distance 136 from the first surface 113.

To measure the temperature of a single substrate at a single location (e.g., the center of substrate 112), the light source 202 sends a light beam to the isolating element 204. The isolating element 204 allows the light from the light source to pass the coupling element 140. The isolating element 204 further prevents any of the light from flowing back towards the light source 202 or in any direction other than into the coupling element 140. At the multiplexing unit 212, the light passes through in a single beam, without any de-multiplexing, because the light is intended to be incident on a single spot of the substrate. Alternatively or optionally, the multiplexing unit 212 may be bypassed or omitted from the light path circuit. Therefore, light leaving the coupling element 140 propagates directly into one optical fiber directed to a particular location of the substrate to be measured (e.g., optical fiber 132a disposed in the opening 122, for measuring the temperature at the center of a substrate 112, when present). After exiting the optical fiber through the first end 134 (optionally, via the optical probe 144), the light traverses the first distance 136 and irradiates the first surface 113.

Upon irradiating the first surface 113 at a first time (t₁), a portion of the incident light is reflected by the first surface 113 to form a first reflected light beam. The rest of the incident light is transmitted through the first surface 113 and travels a further distance equal to the thickness of the substrate 112. At a later second time (t₂), some of the transmitted light is reflected by an inner boundary of the second surface 115 to form a second reflected beam.

The first and second reflected light beams travel the first distance 136 and are received by the first end 134 for transmission in the optical fiber 132, towards the coupling element 140. However, due to the delay of the second reflected light beam (i.e., t₂>t₁), the two reflected light beams will be out of phase and will interfere with each other when they combine during propagation. The coupling element 140 directs the reflected light beams into the photodetector 208. The photodetector 208 senses and transmits the interference signal to the signal processor 210. The signal processor 210 performs a spectral analysis of the interference signal to determine the temperature of the substrate.

The inventors observed that in some processes, for example plasma processing, the temperature profile of the substrate may be non-uniform, for example, the temperature at periphery of the substrate may be different than the temperature at the center of the substrate. Hence, in some embodiments, the substrate processing system 100 may be configured to measure the temperature at different points of the substrate 112.

To measure the temperature a single substrate (e.g., substrate 112 shown in FIG. 1) at a different locations, light provided by the light source 202 is split into separate beams by the de-multiplexer of the multiplexing unit 212. The separate light beams are directed into separate optical fibers (e.g., 132a, 132b, and 132c) to irradiate the substrate 112 at different points on the first surface 113, for example, above the first end 134 of each optical fiber (e.g., 132a, 132b, and 132c). The incident light is reflected off the first and second surfaces (113, 115) at each irradiated location of the substrate 112.

In some embodiments, pairs of reflected light beams (i.e., the first and second reflected light) beams produced at each irradiated location of the substrate 112 are received by the first end 134 of a corresponding optical fiber (e.g., 132a, 132b, and 132c) for propagation towards coupling element 140. The first and second reflected light beams from each substrate location interfere with each other when they combine during propagation into the multiplexing unit 212 before entering the coupling element 140.

The multiplexing unit 212, via the multiplexer, selects and allows the combined reflected light beams from one substrate location at a time. Thus, the photodetector 208 senses and receives discrete interference signals, each due to a pair of reflected light beams from each one of the substrate locations.

The photodetector 208 transmits the discrete interference signals to the signal processor 210. The signal processor 210 performs spectral interferometry on each discrete signal to determine the temperature of the substrate 112 at the different locations. Measuring temperature at different locations of the substrate provides information about the temperature distribution across the substrate 112.

The temperature of multiple substrates stacked one a substrate support may be measured in accordance with some embodiments of the present disclosure. To measure the temperature of each substrate (e.g., 112a, 112b, 112c shown in FIG. 3) at a same corresponding point on each substrate, for example, the center of each substrate, light from the light source 202 propagates directly into the optical fiber provided to deliver light to the particular point or area of the first substrate to be measured (e.g., the center of 112a).

Upon exiting the optical fiber through the first end 134 or, optionally, via the optical probe 144, the light traverses the first distance 136 and irradiates the first surface 113 of the first substrate (e.g., first surface 113a of substrate 112a). A portion of the incident light is reflected by the first surface 113 of the first substrate to form a first reflected light beam. An un-reflected portion of the incident light forms a first transmitted light beam is transmitted through the first surface 113 and across the thickness of the first substrate to reach the second surface 115 of the first substrate (e.g., second surface 115a of substrate 112a). At the second surface 115 of the first substrate, a portion of the first transmitted light beam is reflected by an inner boundary of the second surface 115 of the first substrate (e.g., inner boundary of second surface 115a of substrate 112a) to form a second reflected light beam.

Accordingly, the optical path length of the second reflected light beam is longer than the optical path length of the first reflected light beam by a length corresponding to the thickness of the first substrate (e.g., the thickness of substrate 112a).

An un-reflected portion of the first transmitted light beam becomes a second transmitted light beam and enters the first gap d₁ between the first substrate and the second substrate (e.g., substrate 112a and substrate 112b). Due to refraction, the second transmitted light beam propagates through the first gap d₁ and is incident upon the first surface 113 of the second substrate (e.g., first surface 113b of substrate 112b). A portion of the second transmitted light beam is reflected by the first surface 113 of the second substrate (e.g., first surface 113b of substrate 112b).

The light reflected by the first surface 113 of the second substrate is refracted through the first gap d₁ to be incident on the second surface 115 of the first substrate (e.g., of second surface 115a of substrate 112a). A portion of the light that is incident on the second surface 115 of the first substrate (e.g., substrate 112a) is transmitted across the thickness of the first substrate (e.g., substrate 112a) to form a third reflected light beam. The optical path length of the third reflected light beam is longer than the optical path of the first reflected light beam by twice the distance of the first gap d₁ plus twice the distance of the thickness of the first substrate (e.g., substrate 112a).

An un-reflected portion of the second transmitted light beam becomes a third transmitted light beam which is incident on the first surface 113 of the second substrate (e.g., first surface 113b of substrate 112b). The third transmitted light beam is transmitted through the first surface 113 (e.g., first surface 113b of substrate 112b) and across the thickness of the second substrate (e.g., thickness of substrate 112b) to reach an inner boundary of the second surface 115 of the second substrate (e.g., inner boundary of second surface 115b of substrate 112b). At the inner boundary of the second surface 115 of the second substrate (e.g., second surface 115b of substrate 112b), a portion of the third transmitted light beam is reflected.

The light reflected by the inner boundary of the second surface 115 of the second substrate (e.g., inner boundary of second surface 115b of substrate 112b) is refracted through the first gap d₁ to be incident on the second surface 115 of the first substrate (e.g., second surface 115a of substrate 112a). A portion of the light that is incident on the second surface 115 of the first (e.g., inner boundary of second surface 115a of substrate 112a) is transmitted across the thickness of the first substrate (e.g., substrate 112a) to form a fourth reflected light beam. The optical path length of the fourth reflected light beam is longer than the optical path of the second reflected light beam by twice the distance of the first gap d₁ plus twice the thickness of the second substrate (e.g., substrate 112b). Accordingly, the optical path length of the fourth reflected light beam is longer than the optical path length of the third reflected light beam by a length corresponding to the thickness of the second substrate (e.g., thickness of substrate 112b).

An un-reflected portion of the third transmitted light beam becomes a fourth transmitted light beam and the operation continues until a pair of reflected light beams are reflected from the first and second surfaces of the N^{th} substrate.

Each pair of reflected light beams due to the first to the N^{th} substrate travels the first distance 136 and is received by the first end 134 of the optical fiber 132 for transmission in the optical fiber 132, towards the coupling element 140. However, due to the delay of the reflected light beam from the second surface 115 of each substrate, the two reflected light beams from each substrate will be out of phase and will interfere with each other when they combine during propagation. The coupling element 140 directs the reflected light beams into the photodetector 208. The photodetector 208 senses and transmits the interference signal to the signal processor 210. The signal processor 210 performs a spectral analysis of the interference signal to determine the temperature of the first to the N^{th} substrate (e.g., substrates 112a, 112b, and 112c).

In some embodiments, temperature of multiple substrates (e.g., substrates a, 112b, 112c shown in FIG. 3), may be measured at a different locations of each substrate (e.g., the center and the periphery) provided in accordance with some embodiments of the present disclosure.

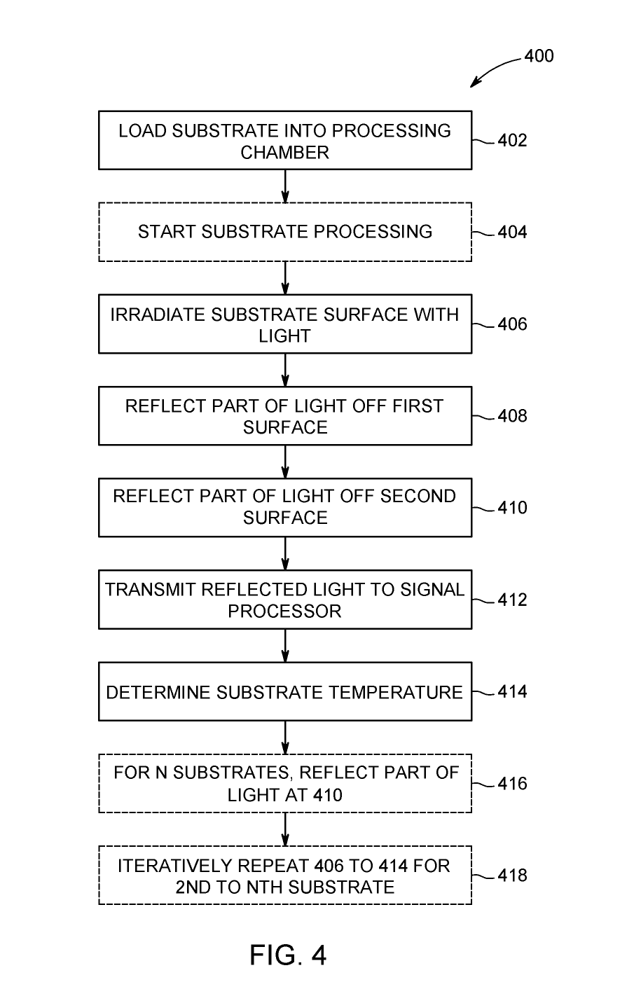

FIG. 4 depicts a flow chart for a method 400 of measuring a temperature of a substrate 112 in accordance with some embodiments of the present disclosure. The method 400 is described below with respect to FIGS. 1 and 3. The method may advantageously provide accurate, robust, and real-time temperature measurement of one or more substrates disposed in a process chamber.

The method begins at 402 by loading a substrate into the process chamber and onto the substrate support. Optionally, as shown at 404, substrate processing may be started in the process chamber. At 406, the substrate on the substrate support is irradiated with an incident light beam. At 408, a first reflection of the incident light is bounced off a first surface 113 of the substrate 112. At 410, a second reflection of the first incident light is bounced off an inner boundary of a second surface 115 opposite the first surface 113. At 412, a temperature of the substrate 112 is determined from a spectral interferometry of the first and second reflections.

To measure the temperature of multiple substrates, for example according to FIG. 3, at 402, load two or more substrates (first to N^{th} substrates) into the process chamber with gaps d₁ to d_{N} between them. At 410 an un-reflected portion of the light bounced off the second surface 115 is refracted through the gap d₁ between the first substrate and the second substrate (e.g., substrates 112a and 112b). At 416, the refracted light is irradiated on the second substrate, similar to the incident light on the substrate at 406. At 418, repeat steps 406 to 414 on the second substrate (e.g., substrate 112b) and iteratively for the remainder of the substrates until the temperature of the N^{th} substrate is determined.

The configuration of the measurement equipment 142 disclosed herein advantageously addresses the inaccuracy, unreliability, and lack of repeatability associated with typical light-based measuring systems, including those utilizing mechanical scanning and light polarization. Consequently, the non-contact substrate temperature measurement technique disclosed herein is more accurate, more robust, and faster than most common thermo-optical measurement methods.

For example, in some embodiments, the temperature of a substrate may be performed in less than about 1 second/data point. In some embodiments, for example, for substrates having a thickness more than about 500 μm, the sampling rate of the temperature measurement may be about 22.2 ms/point, with a measurement accuracy of about +/−0.1%. In some embodiments, for example, for substrates having a thickness less than about 500 μm, the sampling rate of the temperature measurement may be about 16.7 ms/point, with a measurement accuracy of about +/−0.5%.

A controller 146 may be provided and coupled to various components of the substrate processing system 100 to control the operation of the substrate processing system 100. The controller 146 includes a central processing unit (CPU) 148, support circuits 150 and a memory or computer readable medium 152. The controller 146 may control the substrate processing system 100 directly, or via computers (or controllers) associated with particular process chamber and/or support system components. The controller 146 may be any form of general-purpose computer processor that can be used in an industrial setting for controlling various chambers and sub-processors. The memory, or computer readable medium, 152 of the controller 146 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 150 are coupled to the CPU 148 for supporting the processor in a conventional manner. These circuits include cache, power supplies, clock circuits, input/output circuitry and subsystems, and the like. Inventive methods as described herein, such as the method for measuring a temperature of a substrate, may be stored in the memory 152 as software routine 154 that may be executed or invoked to control the operation of the substrate processing system 100 in the manner described herein. The software routine may also be stored and/or executed by a second CPU (not shown) that is remotely located from the hardware being controlled by the CPU 148.

Thus, improved substrate temperature measuring systems and substrate supports incorporating such substrate temperature measuring systems have been provided herein. The substrate temperature measuring systems disclosed herein provide accurate, robust, and real-time temperature measurements of one or more substrates disposed in a process chamber.

While the foregoing is directed to embodiments of the present disclosure, other and further embodiments of the disclosure may be devised without departing from the basic scope thereof.

1. An apparatus for processing substrates, comprising:
a process chamber;
a substrate support within the process chamber to support a substrate for processing;
a light source directly coupled to a light isolator and configured to deliver incident light to and through a first surface of the substrate when disposed on the substrate support;
an optical fiber having a first end spaced apart a first distance from the first surface and a second end directly coupled to the light source via a coupling element;
a photodetector directly coupled to the second end of the optical fiber via the coupling element and configured to receive a first reflected light beam reflected off the first surface and a second reflected light beam reflected off an inner boundary of a second surface of the substrate, opposite the first surface; and
a signal processor to determine a temperature of the substrate based on the first and second reflected light beams.

2. The apparatus of claim 1, wherein the first distance is about 155 mm.

3. The apparatus of claim 1, wherein the substrate support further comprises:
a gas hole disposed through a central axis of the substrate support;
one or more holes formed in the substrate support, about the gas hole; and
a corresponding number of lift pins disposed in the one or more holes;
wherein the gas hole and lift pins are configured to hold an optical probe coupled to the first end and disposed between the first end and the first surface.

4. The apparatus of claim 3, further comprising a plurality of optical probes disposed in the lift pins and gas hole, wherein the optical fiber couples light source to the optical probes via a multiplexing unit.

5. The apparatus of claim 1, further comprising one or more electrodes disposed in the substrate support.

6. The apparatus of claim 1, further comprising a heating apparatus disposed in the substrate support.

7. The apparatus of claim 1, wherein the substrate support further comprises a cooling apparatus disposed in the substrate support.

8. The apparatus of claim 1, further comprising a thermocouple disposed in or proximate the substrate support.

9. The apparatus of claim 1, further comprising a multiple-substrate holder, the multiple-substrate holder comprising:
a bottom member;
one or more vertical supports extending from the bottom member; and
a plurality of vertically spaced apart substrate support planes attached to the vertical supports, wherein each substrate support plane holds a substrate when multiple substrates are disposed in the process chamber.

10. The apparatus of claim 9, wherein the light source is configured to deliver light to and through a first surface of each substrate when disposed mounted on the multiple-substrate holder;
wherein a photodetector is configured to receive first reflected light beams reflected off the first surface of each substrate and second reflected light beams reflected off an inner boundary of a second surface of each substrate, opposite the first surface of each substrate; and
wherein a signal processor is configured to determine a temperature of each substrate based on the first and second reflected light beams corresponding to each substrate.

11. A method for measuring a temperature of a substrate comprising:
(a) irradiating a substrate inside a processing chamber with light;
(b) receiving a first reflection of the light from a first surface of the substrate;
(c) receiving a second reflection of the light through the substrate from an inner boundary of a second surface opposite the first surface; and
(d) determining a substrate temperature based on a spectral analysis of an interference pattern of the first and second reflections.

12. The temperature measuring method of claim 11, wherein the substrate comprises silicon.

13. The temperature measuring method of claim 11, wherein the light has a wavelength between about 1100 nm and about 1400 nm.

14. The temperature measuring method of claim 11, wherein the light is provided by a superluminiscent diode (SLD).

15. The temperature measuring method of claim 11, wherein the first and second reflections are transmitted in an optical fiber to a photodetector, wherein, during propagation in the optical fiber, the first and second reflections are combined to form an interference signal.

16. The temperature measuring method of claim 11, further comprising repeating steps (a) to (d).

17. The temperature measuring method of claim 11, further comprising determining a temperature of two or more substrates disposed in the processing chamber.

18. The temperature measuring method of claim 11, further comprising simultaneously measuring the temperature at different locations of one or more substrates.

19. The temperature measuring method of claim 11, wherein the temperature of the substrate is measured in less than about 1 second.

20. A non-transitory computer readable medium having instructions stored thereon that, when executed, cause a method measuring a temperature of a substrate, the method comprising:
irradiating a substrate inside a processing chamber with light;
receiving a first reflection of the light from a first surface of the substrate;
receiving a second reflection of the light through the substrate from an inner boundary of a second surface opposite the first surface; and
determining a substrate temperature based on a spectral analysis of an interference pattern of the first and second reflections.
